(19) United States
(12) Patent Application Publication
(10) Pub. No.: US 2025/0266377 A1
(43) Pub. Date: Aug. 21, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 18/679,449

(22) Filed: May 31, 2024

(30) Foreign Application Priority Data
Feb. 16, 2024 (KR) 10-2024-0022410

(51) Int. Cl. H01L 23/00; H01L 23/522; H01L 23/528; H01L 23/532; H01L 25/18; H10B 80/00

(52) U.S. Cl. CPC H01L 24/05; H01L 23/5226; H01L 23/5283; H01L 23/53295; H01L 24/03; H01L 24/08; H01L 24/80; H01L 25/18; H10B 80/00; H01L 2224/039; H01L 2224/05541; H01L 2224/05687; H01L 2224/08058; H01L 2224/08059; H01L 2224/0807; H01L 2224/08146; H01L 2224/80345; H01L 2224/80359; H01L 2224/80365; H01L 2224/80379; H01L 2225/06544; H01L 2924/35121

(57) ABSTRACT

A semiconductor device may include a peripheral circuit comprising a plurality of transistors, a cell array and a contact array positioned adjacent to each other over the peripheral circuit, a bonding pad for electrically connecting the peripheral circuit with the cell array and the contact array, the bonding pad comprising first and second portions, wherein the first portion has a first width and is in electrical connection with at least one transistor of the peripheral circuit, wherein the second portion has a second width that is less than the first width of the first portion, and wherein a bonding via electrically connecting the bonding pad with the contact array or the cell array extends partially inside the first portion of the bonding pad.

### CROSS-REFERENCE TO RELATED APPLICATION

This application claims priority under 35 U.S.C. § 119 to Korean Patent Application No. 10-2024-0022410 filed on Feb. 16, 2024, which is incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed to improve operation reliability of the semiconductor device.

### SUMMARY

According to an embodiment of the present disclosure, a three-dimensional semiconductor device (hereinafter referred to simply as semiconductor device) may include a cell array disposed over or on a peripheral circuit, a bonding pad for electrically connecting the peripheral circuit with the cell array, and a bonding via inside the bonding pad.

According to an embodiment of the present disclosure, a semiconductor device may include a peripheral circuit comprising a plurality of transistors, a cell array and a contact array positioned adjacent to each other over the peripheral circuit, a bonding pad for electrically connecting the peripheral circuit with the cell array and the contact array, the bonding pad comprising first and second portions, wherein the first portion has a first width and is in electrical connection with at least one transistor of the peripheral circuit, wherein the second portion has a second width that is less than the first width of the first portion, and wherein a bonding via electrically connecting the bonding pad with the contact array or the cell array extends partially inside the first portion of the bonding pad.

According to an embodiment of the present disclosure, a method of manufacturing a semiconductor device may include forming a first wafer including a preliminary bonding pad, forming a second wafer including a substrate, an interlayer insulating layer disposed over or on the substrate, a bonding via positioned in the interlayer insulating layer, and a trench exposing the bonding via, bonding the first wafer and the second wafer so that the preliminary bonding pad and the bonding via contact each other, and forming a bonding pad surrounding the bonding via by expanding the preliminary bonding pad into the trench.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a diagram illustrating a semiconductor device according to an embodiment of the present disclosure.

FIGS. 2A and 2B are diagrams illustrating a semiconductor device according to an embodiment of the present disclosure.

FIG. 3 is a diagram illustrating a semiconductor device according to an embodiment of the present disclosure.

FIGS. 4A to 6 are diagrams illustrating a method of manufacturing a semiconductor device according to an embodiment of the present disclosure.

FIGS. 7 and 8 are diagrams illustrating a method of manufacturing a semiconductor device according to an embodiment of the present disclosure.

FIGS. 9 and 10 are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to embodiments of the present disclosure, a semiconductor device having a stable structure and improved reliability may be provided.

Hereinafter, embodiments according to the technical concepts of the present disclosure are described with reference to the accompanying drawings.

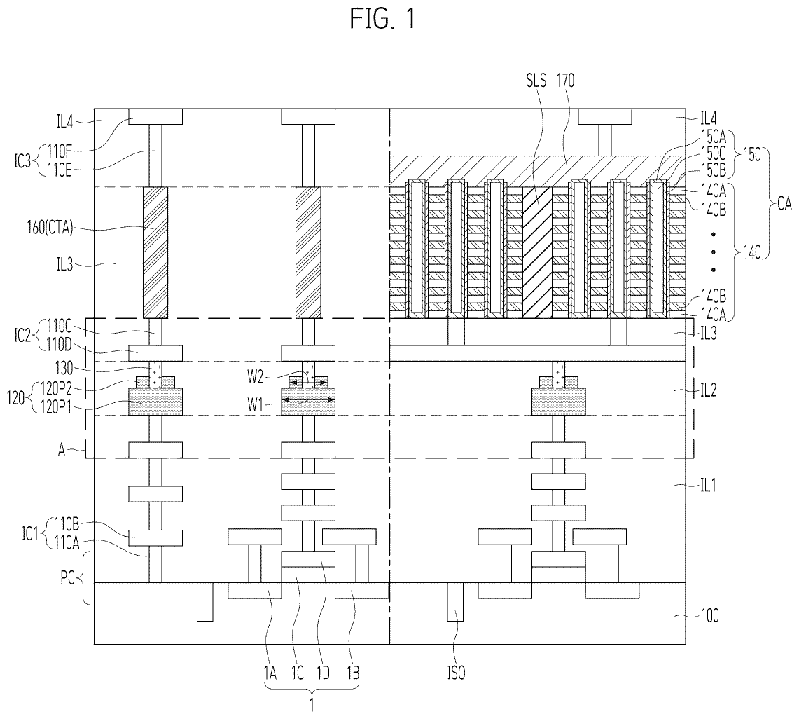

FIG. 1 is a diagram illustrating a semiconductor device according to an embodiment of the present disclosure.

Referring to FIG. 1, the semiconductor device may include at least one of a substrate 100, a first interconnection structure IC1, a second interconnection structure IC2, a third interconnection structure IC3, a bonding pad 120, a bonding via 130, a gate structure 140, channel structures 150, contact plugs 160, and a source structure 170. The semiconductor device may further include at least one of a slit structure SLS, an isolation layer ISO, a first interlayer insulating layer IL1 disposed over the substrate, a second interlayer insulating layer IL2 disposed over the first interlayer insulating layer IL1, a third interlayer insulating layer IL3 disposed over the second interlayer insulating layer IL2, and a fourth interlayer insulating layer IL4 disposed over the third interlayer insulating layer IL3.

A peripheral circuit PC may be disposed over or on the substrate 100. The peripheral circuit PC may include at least one transistor 1, typically a plurality of transistors 1. Each of the transistors 1 may include junctions 1A and 1B, a gate electrode 1D, and a gate insulating layer 1C. For example, the gate insulating layer 1C may be positioned between the gate electrode 1D and the substrate 100. The isolation layer ISO may be positioned in the substrate 100, and an active region of the transistor 1 may be defined by the isolation layer ISO. The transistors 1 may serve different functions such as amplification, switching, and signal processing, thus supporting the overall operation of the semiconductor device.

A cell array CA may be disposed over or on the peripheral circuit PC. The cell array CA may include the gate structure 140 and the channel structures 150. The gate structure 140 may include insulating layers 140A and conductive layers 140B that are alternately stacked. The insulating layers 140A may include an insulating material such as an oxide, and the conductive layers 140B may include a conductive material such as tungsten, polysilicon, or molybdenum. The channel structures 150 may extend through the gate structure 140. A source structure 170 may be disposed over or on the cell array CA, and the channel structures 150 may extend into the source structure 170 through the gate structure 140. Each of the channel structures 150 may include at least one of a channel layer 150A, a memory layer 150B surrounding the channel layer 150A, and an insulating core 150C in the channel layer 150A. The slit structure SLS may extend through the gate structure 140. The slit structure SLS may include an insulating material, a conductive material, a semiconductor material, or the like.

The conductive layers 140B may be gate lines such as a source select line, a word line, or a drain select line. A source select transistor, a memory cell, or a drain select transistor may be positioned in a region where the channel structures 150 and the conductive layers 140B intersect. In an embodiment, at least one source select transistor, a plurality of memory cells, and at least one drain select transistor stacked along the channel structure 150 may configure one memory string.

A contact array CTA may be disposed over or on the peripheral circuit PC. The contact array CTA may be positioned at a same level as the cell array CA and may include the plurality of contact plugs 160 spaced apart from each other. The contact plugs 160 may be positioned in the third interlayer insulating layer IL3. Each of the contact plugs 160 may extend through the entire third interlayer layer IL3. The contact plugs 160 may be positioned in the third interlayer insulating layer IL3. The contact plugs 160 may include a conductive material such as tungsten.

The first interconnection structure IC1 may be disposed over or on the peripheral circuit PC. The first interconnection structure IC1 may be positioned in the first interlayer insulating layer IL1. For example, the first interlayer insulating layer IL1 may be disposed over or on the substrate 100. The first interconnection structure IC1 may include first contact vias 110A and first contact lines 110B. At least one of the first contact vias 110A may be connected to the transistor 1 and may connect the first contact lines 110B to each other. The first contact vias 110A may extend in a vertical direction to a top surface of the substrate 100. The first contact lines 110B may extend in a direction parallel to the top surface of the substrate 100. A plurality of parallel first contact lines 110b may be arranged at different distances from the substrate 100 inside the first interlayer insulating layer IL1. The first interconnection structure IC1 may include a conductive material such as tungsten. The first interlayer insulating layer IL1 may include an insulating material such as an oxide or a nitride.

The second interconnection structure IC2 may be disposed over or on, for example as illustrated on the first interconnection structure IC1 and may be positioned under the cell array CA and/or the contact array CTA. The second interconnection structure IC2 may be positioned in the third interlayer insulating layer IL3. For example, the third interlayer insulating layer IL3 may be disposed over or on second interlayer insulating layer IL2. The second interconnection structure IC2 may include second contact vias 110C and second contact lines 110D. At least one of the second contact vias 110C may be connected to the channel structures 150 and may be connected to at least one of the contact plugs 160. The second contact lines 110D may be connected to at least one of the second contact vias 110C. The second interconnection structure IC2 may include a conductive material such as tungsten. The third interlayer insulating layer IL3 may include an insulating material such as an oxide or a nitride.

The bonding pad 120 may be positioned between the peripheral circuit PC and the cell array CA. Alternatively, the bonding pad 120 may be positioned between the peripheral circuit PC and the contact array CTA. The bonding pad 120 may be positioned in the second interlayer insulating layer IL2. For example, the second interlayer insulating layer IL2 may be positioned between the first interlayer insulating layer IL1 and the third interlayer insulating layer IL3. The bonding pad 120 may include a first portion 120P1 having a first width W1 and a second portion 120P2 having a second width W2. The first width W1 may be substantially equal to or different from the second width W2. For example, the second width W2 may be less than the first width W1.

The bonding pad 120 may electrically connect the peripheral circuit PC and the cell array CA. Alternatively, the bonding pad 120 may electrically connect the peripheral circuit PC and the contact array CTA. For example, the bonding pad 120 may electrically connect the peripheral circuit PC and the cell array CA through the first interconnection structure IC1 and the second interconnection structure IC2. Alternatively, the bonding pad 120 may electrically connect the peripheral circuit PC and the contact array CTA through the first interconnection structure IC1 and the second interconnection structure IC2. The bonding pad 120 may include a conductive material such as copper.

The bonding via 130 may be disposed over or on the bonding pad 120. The bonding via 130 may extend to the first portion 120P1 of the bonding pad 120 by passing through the second portion 120P2 of the bonding pad 120. For example, the second portion 120P2 of the bonding pad 120 may surround a portion of a sidewall of the bonding via 130. In this case, a lower surface of the bonding via 130 may contact the first portion 120P1 of the bonding pad 120, and a side wall of the bonding via 130 may contact the second portion 120P2 of the bonding pad 120. A contact area between the bonding via 130 and the bonding pad 120 may be increased. Therefore, electrical connectivity between the bonding via 130 and the bonding pad 120 may be improved.

The bonding via 130 may include a material substantially equal to or different from that of the bonding pad 120. As an example, the bonding via 130 may include copper as the material substantially equal to that of the bonding pad 120. In this case, an interface between the bonding pad 120 and the bonding via 130 might not exist. As another example, the bonding via 130 may include tungsten as the material different from that of the bonding pad 120. In this case, the interface between the bonding pad 120 and the bonding via 130 may exist.

The third interconnection structure IC3 may be disposed over or on the cell array CA or the contact array CTA, and may be electrically connected to the cell array CA or the contact array CTA. For example, the third interconnection structure IC3 may be disposed over or on the source structure 170 and may be electrically connected to the source structure 170. The third interconnection structure IC3 may be disposed over or on the contact plugs 160 and may be electrically connected to the contact plugs 160. The third interconnection structure IC3 may be positioned in the fourth interlayer insulating layer IL4. For example, the fourth interlayer insulating layer IL4 may be disposed over or on the third interlayer insulating layer IL3. Alternatively, the fourth interlayer insulating layer IL4 may be disposed over or on the source structure 170.

The third interconnection structure IC3 may include third contact vias 110E and third contact lines 110F. At least one of the third contact vias 110E may be connected to the contact plug 160. At least one of the third contact vias 110E may be connected to the source structure 170. At least one of the third contact lines 110F may be connected to the third contact via 110E. The third interconnection structure IC3 may include a conductive material such as tungsten. The fourth interlayer insulating layer IL4 may include an insulating material such as an oxide or a nitride. The first, second, and third contact vias, 110A, 110C, and 110E may be in the form of vertical lines, i.e., they may be perpendicular to the top surface of the substrate 100. The first, second, and third contact lines 110B, 110D, and 110F may be in the form of horizontal lines, i.e., they may be extending in parallel to the top surface of the substrate 100.

According to the structure described above, the bonding pad 120 may include the second portion 120P2 having the second width W2 less than the first width W1 of the first portion 120P1. The bonding via 130 may extend to the first portion 120P1 by passing through the second portion 120P2. In this case, the contact area between the bonding via 130 and the bonding pad 120 may be increased, and thus electrical connectivity between the bonding via 130 and the bonding pad 120 may be improved.

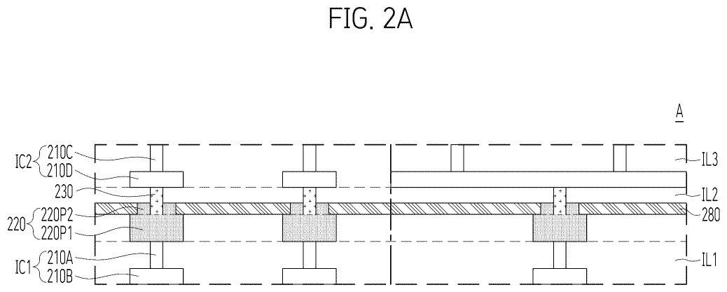

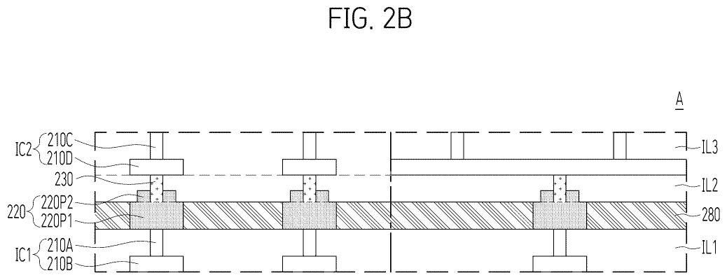

FIGS. 2A and 2B are diagrams illustrating a semiconductor device according to an embodiment of the present disclosure. FIGS. 2A and 2B may be enlarged views of A of FIG. 1. Hereinafter, any content that overlaps with the content described above may be omitted.

Referring to FIGS. 2A and 2B, the semiconductor device may include at least one of a first interconnection structure IC1, a second interconnection structure IC2, a bonding pad 220, a bonding via 230, and a bonding layer 280. The semiconductor device may further include at least one of a first interlayer insulating layer IL1, a second interlayer insulating layer IL2, and a third interlayer insulating layer IL3.

The first interconnection structure IC1 may be positioned in the first interlayer insulating layer IL1. The first interconnection structure IC1 may include first contact vias 210A and first contact lines 210B.

The bonding pad 220 may be disposed over or on the first interconnection structure IC1. The bonding pad 220 may be positioned in the first interlayer insulating layer IL1 and the bonding layer 280 or in the second interlayer insulating layer IL2, and the bonding layer 280. In an embodiment, the bonding pad 220 may be positioned in the first interlayer insulating layer IL1, the second interlayer insulating layer IL2, and the bonding layer 280. The bonding pad 220 may include a first portion 220P1 having a first width W1 and a second portion 220P2 having a second width W2 which may be less than the first width W1. Referring to FIG. 2A, the second portion 220P2 of the bonding pad 220 may be positioned in the bonding layer 280, and the first portion 220P1 of the bonding pad 220 may be positioned in the first interlayer insulating layer IL1. Referring to FIG. 2B, the first portion 220P1 of the bonding pad 220 may be positioned in the bonding layer 280, and the second portion 220P2 may be positioned in the second interlayer insulating layer IL2. For example, the bonding layer 280 may be positioned between the first interlayer insulating layer IL1 and the second interlayer insulating layer IL2. The second interlayer insulating layer IL2 may be disposed over or on the first interlayer insulating layer IL1. The bonding pad 220 may include a conductive material such as copper. In an embodiment, the first portion 220P1 and the second portion 220P2 of the bonding pad 220 may be positioned in the bonding layer 280.

The bonding layer 280 may include a material substantially equal to or different from that of the first interlayer insulating layer IL1 or the second interlayer insulating layer IL2. For example, the bonding layer 280 may include a nitride, and the first interlayer insulating layer IL1 and the second interlayer insulating layer IL2 may include an oxide. Using nitride for the bonding layer 280 is advantageous because it may increase the bonding force at an interface between the bonding layer 280 and each of the interlayer insulating layers IL1 and IL2. For example, referring to FIG. 2A, the bonding force between the bonding layer 280 and the first interlayer insulating layer IL1 may increase. Referring to FIG. 2B, the bonding force between the bonding layer 280 and the second interlayer insulating layer IL2 may increase.

The bonding via 230 may be positioned on the bonding pad 220. The bonding via 230 may be positioned in the second interlayer insulating layer IL2. The bonding via 230 may extend to the first portion 220P1 of the bonding pad 220 by passing through the second portion 220P2 of the bonding pad 220. Therefore, the second portion 220P2 of the bonding pad 220 may surround a portion of a sidewall of the bonding via 230. In this case, electrical connectivity between the bonding via 230 and the bonding pad 220 may be improved.

The bonding via 230 may include a material substantially equal to or different from that of the bonding pad 220. For example, the bonding via 230 may include tungsten as the material different from that of the bonding pad 220. In this case, an interface between the bonding pad 220 and the bonding via 230 may exist.

The second interconnection structure IC2 may be disposed over or on the bonding via 230. The second interconnection structure IC2 may be positioned in the third interlayer insulating layer IL3. The third interlayer insulating layer IL3 may be disposed over or on the second interlayer insulating layer IL2. The second interconnection structure IC2 may include second contact vias 210C and second contact lines 210D.

According to the structure described above, the bonding layer 280 may be positioned between the first interlayer insulating layer IL1 and the second interlayer insulating layer IL2. In this case, bonding force may increase at the interface between the bonding layer 280 and the interlayer insulating layers IL1 and IL2.

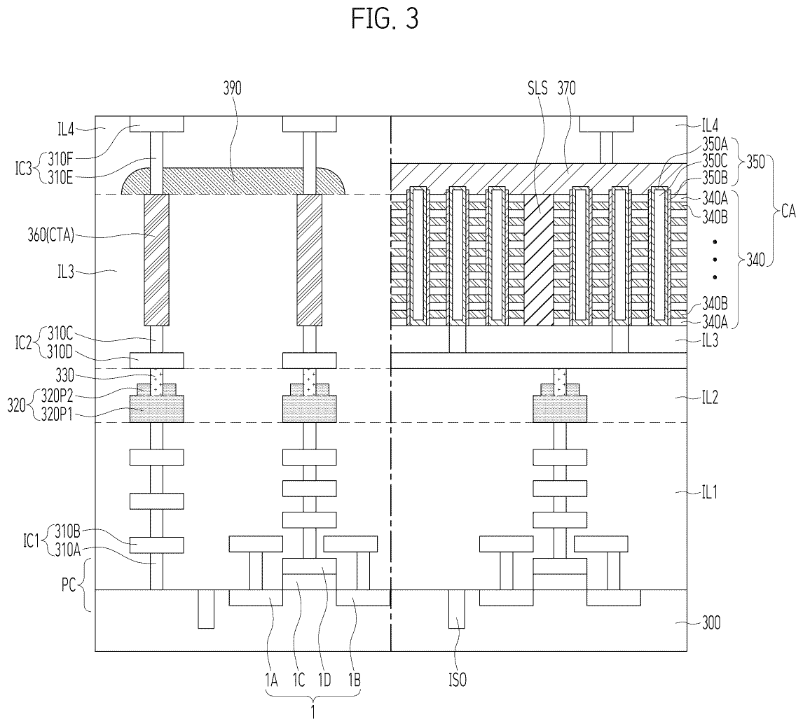

FIG. 3 is a diagram illustrating a semiconductor device according to an embodiment of the present disclosure. Hereinafter, any content that overlaps with the content described above may be omitted.

Referring to FIG. 3, the semiconductor device may include at least one of a substrate 300, a first interconnection structure IC1, a second interconnection structure IC2, a third interconnection structure IC3, a bonding pad 320, a bonding via 330, a gate structure 340, channel structures 350, contact plugs 360, a source structure 370, and a protective layer 390. The semiconductor device may further include at least one of a slit structure SLS, an isolation layer ISO, a first interlayer insulating layer IL1, a second interlayer insulating layer IL2, a third interlayer insulating layer IL3, and a fourth interlayer insulating layer IL4.

A peripheral circuit PC may be disposed over or on the substrate 300. A cell array CA and a contact array CTA may be disposed over or on the peripheral circuit PC. The cell array CA and the contact array CTA may be positioned at a same level from the substrate 300. The cell array CA may include the gate structure 340 and the channel structures 350 arranged spaced part from each other inside the gate structure 340. The contact array CTA may include the contact plugs 360. For reference, the cell array CA may be positioned in a chip region of the semiconductor device, and the contact array CTA may be positioned in a sealing region of the semiconductor device. For example, the sealing region may be a region surrounding the chip region to protect the chip region in a process of manufacturing the semiconductor device.

The gate structure 340 may include insulating layers 340A and conductive layers 340B that are alternately stacked. The channel structures 350 may extend through the gate structure 340. The source structure 370 may be disposed over, or as illustrated, on the cell array CA, and the channel structures 350 may extend into the source structure 370 through the gate structure 340. Each of the channel structures 350 may include at least one of a channel layer 350A, a memory layer 350B surrounding the channel layer 350A, and an insulating core 350C in the channel layer 350A.

The first interconnection structure IC1 may be disposed over, or as illustrated, on the peripheral circuit PC. The first interconnection structure IC1 may be positioned in the first interlayer insulating layer IL1. For example, the first interlayer insulating layer IL1 may be disposed over, or as illustrated, on the substrate 300. The first interconnection structure IC1 may include first contact vias 310A and first contact lines 310B.

The second interconnection structure IC2 may be disposed over, or as illustrated, on the first interconnection structure IC1 and may be positioned under the cell array CA and the contact array CTA. The second interconnection structure IC2 may be positioned in the third interlayer insulating layer IL3. The third interlayer insulating layer IL3 may be disposed over, or as illustrated, on the first interlayer insulating layer IL1. The second interconnection structure IC2 may include second contact vias 310C and second contact lines 310D.

The bonding pad 320 may be positioned between the peripheral circuit PC and the cell array CA. Alternatively, the bonding pad 320 may be positioned between the peripheral circuit PC and the contact array CTA. The bonding pad 320 may be positioned in the second interlayer insulating layer IL2. For example, the second interlayer insulating layer IL2 may be positioned between the first interlayer insulating layer IL1 and the third interlayer insulating layer IL3. The bonding pad 320 may include a first portion 320P1 having a first width W1 and a second portion 320P2 having a second width W2 less than the first width W1.

The bonding pad 320 may electrically connect the peripheral circuit PC and the cell array CA, and may electrically connect the peripheral circuit PC and the contact array CTA. For example, the bonding pad 320 may electrically connect the peripheral circuit PC and the cell array CA through the first interconnection structure IC1 and the second interconnection structure IC2, and may electrically connect the peripheral circuit PC and the contact array CTA through the interconnection structure IC1 and the second interconnection structure IC2. The bonding pad 320 may include a conductive material such as copper.

The bonding via 330 may be disposed over, or as illustrated, on the bonding pad 320. The bonding via 330 may extend to the first portion 320P1 of the bonding pad 320 by passing through the second portion 320P2 of the bonding pad 320. Therefore, the second portion 320P2 of the bonding pad 320 may surround a portion of a sidewall of the bonding via 330.

The bonding via 330 may include a material substantially equal to or different from that of the bonding pad 320. For example, the bonding via 330 may include tungsten as the material different from that of the bonding pad 320. For example, an interface between the bonding pad 320 and the bonding via 330 may exist.

The protective layer 390 may be disposed over, or as illustrated, on the contact array CTA. For example, the protective layer 390 may be disposed over, or as illustrated, on the contact plugs 360. The protective layer 390 may be positioned in the sealing region of the semiconductor device. For example, the protective layer 390 may be positioned in the fourth interlayer insulating layer IL4. The fourth interlayer insulating layer IL4 may be disposed over, or as illustrated, on the third interlayer insulating layer IL3 and may be disposed over, or as illustrated, on the source structure 370. The protective layer 390 may prevent or reduce damage to the substrate on which the protective layer 390 is formed in a process of forming the contact plugs 360. The protective layer 390 may include an insulating material such as an oxide.

The third interconnection structure IC3 may be disposed over, or as illustrated, on the cell array CA or the contact array CTA, and may be electrically connected to the cell array CA or the contact array CTA. For example, the third interconnection structure IC3 may be disposed over, or as illustrated, on the source structure 370 and may be electrically connected to the source structure 370. The third interconnection structure IC3 may be disposed over, or as illustrated, on the contact plugs 360 and may be electrically connected to the contact plugs 360. The third interconnection structure IC3 may be connected to the contact array CTA through the protective layer 390. The third interconnection structure IC3 may be positioned in the fourth interlayer insulating layer IL4. The third interconnection structure IC3 may include third contact vias 310E and third contact lines 310F.

For reference, although not shown in this drawing, a bonding layer may be positioned between the first interlayer insulating layer IL1 and the second interlayer insulating layer IL2. For example, the bonding layer 280 of FIGS. 2A and 2B may be positioned between the first interlayer insulating layer IL1 and the second interlayer insulating layer IL2. For example, the bonding layer may increase bonding force at an interface with the interlayer insulating layers IL1 and IL2.

According to the structure described above, the protective layer 390 may be disposed over, or as illustrated, on the contact array CTA. The protective layer 390 may be positioned in the sealing region surrounding the chip region where the cell array CA of the semiconductor device is positioned. The protective layer 390 may prevent or reduce damage to the substrate on which the protective layer 390 is formed in a process of forming the contact plugs 360 of the contact array CTA.

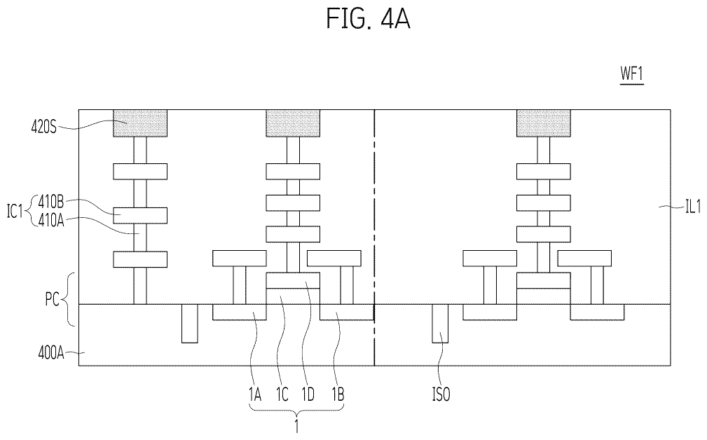

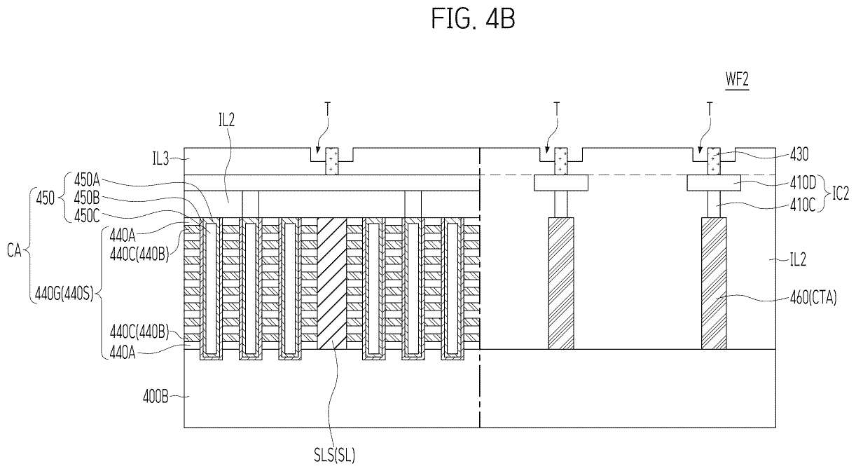

FIGS. 4A to 6 are diagrams illustrating a method of manufacturing a semiconductor device according to an embodiment of the present disclosure. Hereinafter, any content that overlaps with the content described above may be omitted.

Referring to FIG. 4A, a first wafer WF1 may be formed. A peripheral circuit PC may be formed over or on a first substrate 400A. The peripheral circuit PC may include at least one transistor 1. An isolation layer ISO may be formed in the first substrate 400A and may define an active region of the transistor 1.

A first interconnection structure IC1 may be formed on the first substrate 400A. The first interconnection structure IC1 may be formed in a first interlayer insulating layer IL1. For example, the first interlayer insulating layer IL1 may be formed on the first substrate 400A. The first interconnection structure IC1 may include a first contact via 410A and a first contact line 410B. The first contact via 410A may be connected to the peripheral circuit PC. Alternatively, the first contact via 410A may connect the first contact lines 410B. The first interconnection structure IC1 may include a conductive material such as tungsten. The first interlayer insulating layer IL1 may include an insulating material such as an oxide.

A preliminary bonding pad 420S may be formed on the first interconnection structure IC1. The preliminary bonding pad 420S may be formed in the first interlayer insulating layer IL1. The preliminary bonding pad 420S may be connected to the peripheral circuit PC through the first interconnection structure IC1. The preliminary bonding pad 420S may include a conductive material such as copper.

Referring to FIG. 4B, a second wafer WF2 may be formed. A stack 440S may be formed by alternately stacking first material layers 440A and second material layers 440B over or on a second substrate 400B. For example, the first material layers 440A may include an insulating material such as an oxide, and the second material layers 440B may include a sacrificial material such as a nitride.

Channel structures 450 extending into the second substrate 400B through the stack 440S may be formed. Each of the channel structures 450 may include a channel layer 450A, a memory layer 450B surrounding the channel layer 450A, and an insulating core 450C in the channel layer 450A.

A slit SL extending through the stack 440S may be formed and the second material layers 440B of the stack 440S may be replaced with third material layers 440C through the slit SL. Accordingly, a gate structure 440G including the first material layers 440A and the third material layers 440C alternately stacked may be defined. For example, the third material layers 440C may include a conductive material such as tungsten. For reference, when the second material layers 440B include a conductive material, a process of replacing the second material layers 440B with the third material layers 440C may be omitted. Accordingly, a cell array CA including the gate structure 440G and the channel structures 450 may be defined.

Subsequently, a slit structure SLS may be formed in the slit SL. The slit structure SLS may include an insulating material, a conductive material, a semiconductor material, or the like.

A second interlayer insulating layer IL2 may be formed on the second substrate 400B. The second interlayer insulating layer IL2 may be formed also on the gate structure 440G. A contact array CTA including contact plugs 460 may be formed over or on the second substrate 400B. The contact plugs 460 may be formed in the second interlayer insulating layer IL2. The second interlayer insulating layer IL2 may include an insulating material such as an oxide.

A second interconnection structure IC2 may be formed on the contact plugs 460. The second interconnection structure IC2 may be formed over or on the gate structure 440G. The second interconnection structure IC2 may be formed in a second interlayer insulating layer IL2. The second interconnection structure IC2 may include a second contact via 410C and a second contact line 410D. The second interconnection structure IC2 may include a conductive material such as tungsten.

A third interlayer insulating layer IL3 may be formed on the second interconnection structure IC2. The third interlayer insulating layer IL3 may include an insulating material such as an oxide. A bonding via 430 may be formed in the third interlayer insulating layer IL3. The bonding via 430 may be connected to the second interconnection structure IC2. The bonding via 430 may include a conductive material such as tungsten.

A trench T exposing the bonding via 430 may be formed. For example, the third interlayer insulating layer IL3 may be etched to form the trench T exposing a sidewall of the bonding via 430. A depth of the trench T may be determined by controlling a time for etching the third interlayer insulating layer IL3. Therefore, the trench T exposing the sidewall of the bonding via 430 may be formed by controlling the time for etching the third interlayer insulating layer IL3.

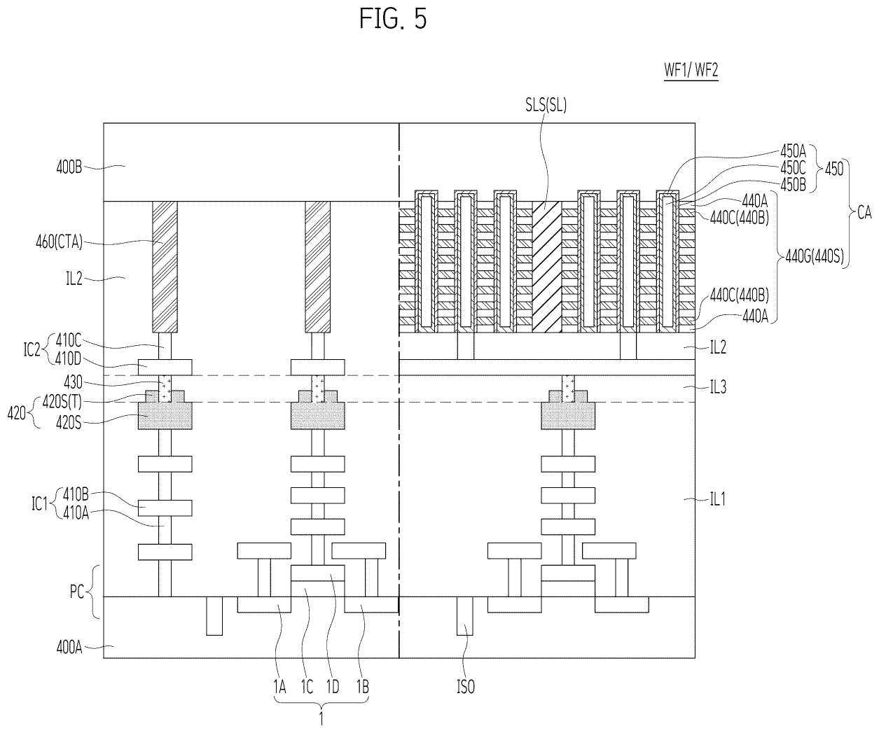

Referring to FIG. 5, the first wafer WF1 and the second wafer WF2 may be bonded. For example, the first wafer WF1 and the second wafer WF2 may be bonded so that a preliminary bonding pad 420S of the first wafer WF1 and the bonding via 430 of the second wafer WF2 are in contact with each other. In a process of bonding the first wafer WF1 and the second wafer WF2, the preliminary bonding pad 420S of the first wafer WF1 may be expanded. In this case, a delamination phenomenon may occur at an interface between the first wafer WF1 and the second wafer WF2.

According to an embodiment of the present disclosure, the preliminary bonding pad 420S of the first wafer WF1 may be expanded into the trench T of the second wafer WF2. Therefore, even though the preliminary bonding pad 420S of the first wafer WF1 is expanded, a delamination phenomenon might not occur at the interface between the first wafer WF1 and the second wafer WF2. As the preliminary bonding pad 420 is expanded into the trench T, the bonding pad 420 surrounding the bonding via 430 of the second wafer WF2 may be formed.

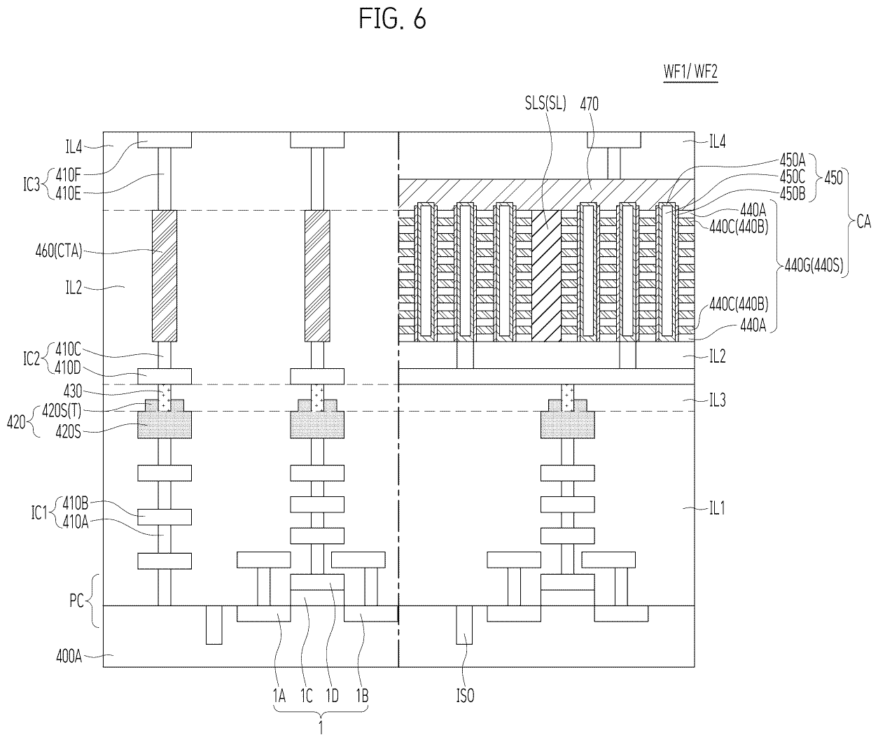

Referring to FIG. 6, the second substrate 400B may be removed to expose the channel structures 450. Subsequently, the memory layer 450B of the channel structures 450 may be partially removed to expose the channel layer 450A. Subsequently, a source structure 470 connected to the channel structures 450 may be formed. For example, the source structure 470 may be connected to the channel layer 450A of the channel structures 450.

Subsequently, a fourth interlayer insulating layer IL4 may be formed on the source structure 470. The fourth interlayer insulating layer IL4 may also be formed on the contact plugs 460. The fourth interlayer insulating layer IL4 may include an insulating material such as an oxide. Subsequently, a third interconnection structure IC3 may be formed in the fourth interlayer insulating layer IL4. The third interconnection structure IC3 may include a third contact via 410E and a third contact line 410F. The third contact via 410e may be connected to the contact plug 460. Alternatively, the third contact via 410E may be connected to the source structure 470. The third interconnection structure IC3 may include a conductive material such as tungsten.

According to the manufacturing method described above, in the process of bonding the first wafer WF1 and the second wafer WF2, the preliminary bonding pad 420S of the first wafer WF1 may be expanded into the trench of the second wafer WF2. Therefore, even though the preliminary bonding pad 420S is expanded, a delamination phenomenon might not occur at the interface between the first and second wafers WF1 and WF2.

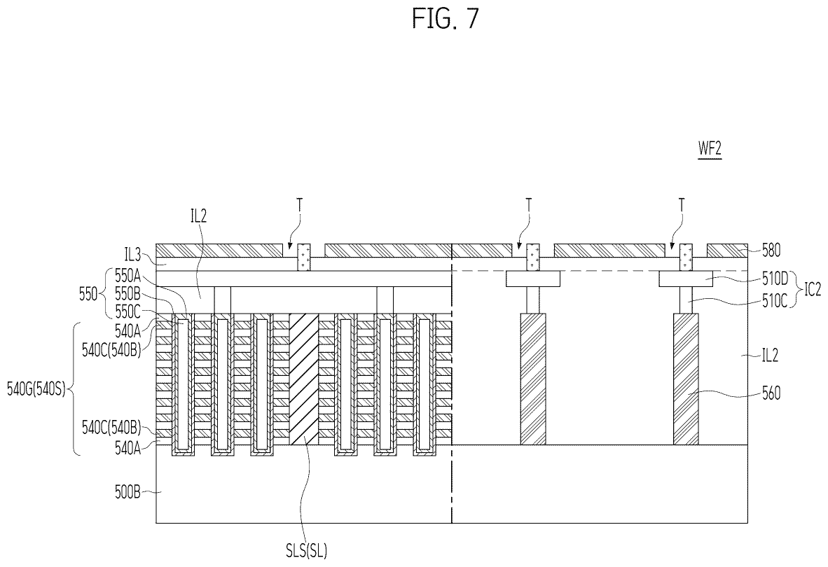

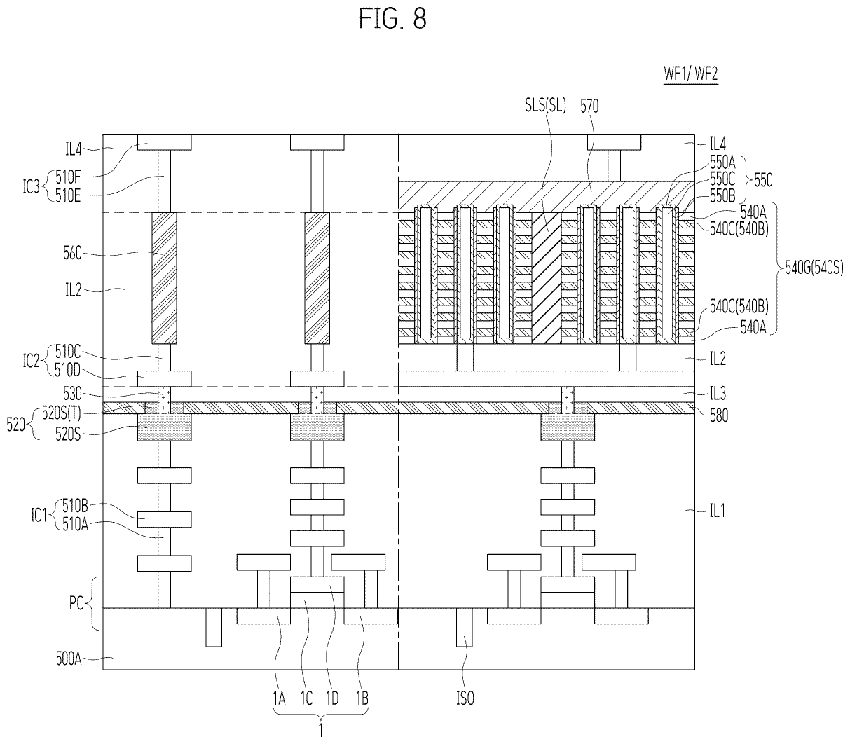

FIGS. 7 and 8 are diagrams illustrating a method of manufacturing a semiconductor device according to an embodiment of the present disclosure. Hereinafter, any content that overlaps with the content described above may be omitted.

Referring to FIG. 7, a second wafer WF2 including a second substrate 500B, a gate structure 540G over or on the second substrate 500B, channel structures 550 extending into the second substrate 500B through the gate structure 540G, a slit structure SLS extending through the gate structure 540G, contact plugs 560 over or on the second substrate 500B, a second interconnection structure IC2 over or on the gate structure 540G and the contact plugs 560, and a bonding via 530 on the second interconnection structure IC2 may be formed.

The contact plugs 560 and the second interconnection structure IC2 may be formed in a second interlayer insulating layer IL2. For example, the second interlayer insulating layer IL2 may be formed on the second substrate 500B. The bonding via 530 may be formed in a third interlayer insulating layer IL3 and a bonding layer 580. For example, the third interlayer insulating layer IL3 may be formed on the second interlayer insulating layer IL2. The bonding layer 580 may be formed on the third interlayer insulating layer IL3. The second interlayer insulating layer IL2 and the third interlayer insulating layer IL3 may include an insulating material such as an oxide, and the bonding layer 580 may include an insulating material such as a nitride.

Subsequently, a trench T exposing the bonding via 530 may be formed. For example, the bonding layer 580 may be etched to form the trench T exposing a sidewall of the bonding via 530.

Referring to FIG. 8, the first wafer WF1 and the second wafer WF2 may be bonded. For example, the first wafer WF1 may include a first substrate 500A, a peripheral circuit PC over or on the first substrate 500A, a first interlayer insulating layer IL1 on the first substrate 500A, a first interconnection structure IC1 in the first interlayer insulating layer IL1, and a preliminary bonding pad 520S in the first interlayer insulating layer IL1.

In a process of bonding the first and second wafers WF1 and WF2, the preliminary bonding pad 520S of the first wafer WF1 may be expanded into the trench T of the second wafer WF2. Therefore, even though the preliminary bonding pad 520S is expanded, a delamination phenomenon might not occur at an interface between the first and second wafers WF1 and WF2.

In addition, because the bonding layer 580 of the second wafer WF2 includes a nitride, the bonding force at an interface between the bonding layer 580 and the first interlayer insulating layer IL1 may be increased. The bonding force between the first and second wafers WF1 and WF2 may increase.

Subsequently, the second substrate 500B may be removed to expose the channel structures 550 and a source structure 570 connected to the channel structures 550 may be formed over or on the channel structure 550. Subsequently, a fourth interlayer insulating layer IL4 may be formed on the source structure 570 and the contact plugs 560. Subsequently, third interconnection structures IC3 may be formed in the fourth interlayer insulating layer IL4. Each of the third interconnection structures IC3 may be connected to the contact plug 560 or the source structure 570.

For reference, although not shown in this drawing, the bonding layer 580 may be formed in a process of forming the first wafer WF1. For example, the preliminary bonding pad 520S may be formed in the bonding layer 580. In this case, bonding force may increase at an interface between the bonding layer 580 and the third interlayer insulating layer IL3 of the second wafer WF2.

Alternatively, the bonding layer 580 may also be formed over or on the first wafer WF1 and the second wafer WF2, respectively. For example, the preliminary bonding pad 520S of the first wafer WF1 may be formed in the bonding layer 580 of the first wafer WF1, and the bonding via 530 of the second wafer WF2 may be formed in the bonding layer 580 of the second wafer WF2. In this case, the bonding layer 580 of the first wafer WF1 and the bonding layer 580 of the second wafer WF2 may be bonded.

According to the manufacturing method described above, the bonding layer 580 may be formed in a process of forming the first wafer WF1. Alternatively, the bonding layer 580 may be formed in a process of forming the second wafer WF2. The bonding layer 580 may include a nitride. Because the bonding layer 580 includes a nitride, the bonding force at an interface between the bonding layer 580 and the interlayer insulating layers IL1 and IL3 may increase. Therefore, the bonding force between the first wafer WF1 and the second wafer WF2 may increase.

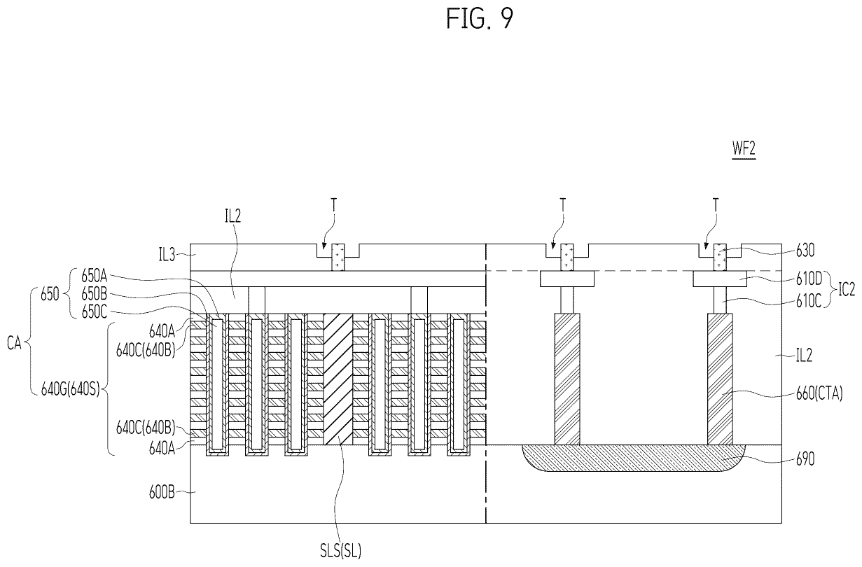

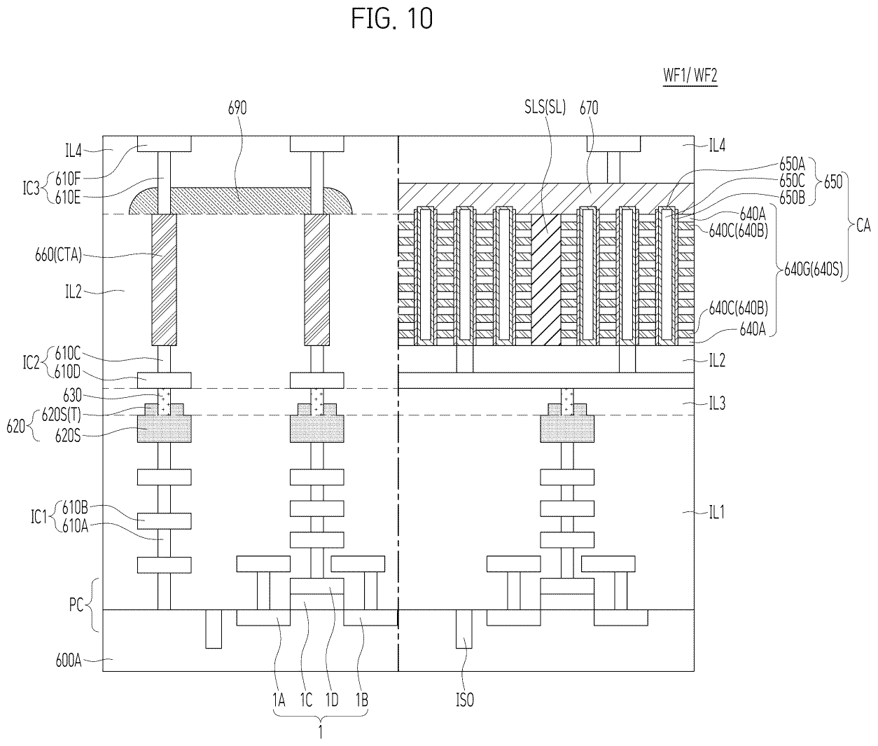

FIGS. 9 and 10 are diagrams illustrating a method of manufacturing a semiconductor device according to an embodiment of the present disclosure. Hereinafter, any content that overlaps with the content described above may be omitted.

Referring to FIG. 9, a second wafer WF2 may be formed. First, a protective layer 690 may be formed in a second substrate 600B. The protective layer 690 may be formed in a sealing region of the substrate. For example, the sealing region may be a region surrounding a chip region to protect the chip region in a process of manufacturing the semiconductor device. For example, the sealing region may be a region surrounding the entire sidewall of the chip region. The protective layer 690 may include an insulating material such as an oxide. Subsequently, the second wafer WF2 including a gate structure 640G over or on the second substrate 600B, channel structures 650 extending into the second substrate 600B through the gate structure 640G, a slit structure SLS extending through the gate structure 640G, contact plugs 660 over or on the second substrate 600B, a second interconnection structure IC2 over or on the gate structure 640G and the contact plugs 660, and a bonding via 630 over or on the second interconnection structure IC2 may be formed.

For example, a cell array CA including the gate structure 640G and the channel structures 650 may be formed in the chip region. A contact array CTA including the contact plugs 660 may be formed in the sealing region. For example, the contact plugs 660 may be formed over or on the protective layer 690. The second substrate 600B may be damaged in a process of forming the contact plugs 660. For example, the second substrate 600B may be exposed in a process of forming contact holes for forming the contact plugs 660. In this case, a portion of the second substrate 600B may be etched and damaged. However, according to an embodiment of the present disclosure, the protective layer 690 may be formed in the second substrate 600B, thereby preventing or minimizing damage to the second substrate 600B in the process of forming the contact holes. The contact plugs 660 and the second interconnection structure IC2 may be formed in a second interlayer insulating layer IL2. For example, the second interlayer insulating layer IL2 may be formed over or on the second substrate 600B. The bonding via 630 may be formed in a third interlayer insulating layer IL3.

Subsequently, a trench T exposing the bonding via 630 may be formed. For example, the third interlayer insulating layer IL3 may be etched to form the trench T exposing a sidewall of the bonding via 630.

Referring to FIG. 10, a first wafer WF1 and the second wafer WF2 may be bonded. For example, the first wafer WF1 may include a first substrate 600A, a peripheral circuit PC over or on the first substrate 600A, a first interlayer insulating layer IL1 over or on the first substrate 600A, a first interconnection structure IC1 in the first interlayer insulating layer IL1, and a preliminary bonding pad 620S in the first interlayer insulating layer IL1.

In a process of bonding the first wafer WF1 and the second wafer WF2, the preliminary bonding pad 620S of the first wafer WF1 may be expanded into the trench T of the second wafer WF2. Therefore, even though the preliminary bonding pad 620S is expanded, a delamination phenomenon might not occur at an interface between the first and second wafers WF1 and WF2.

Subsequently, the second substrate 600B may be removed to expose the channel structures 650. The second substrate 600B may be removed to expose the protective layer 690. Subsequently, a source structure 670 connected to the channel structures 650 may be formed. Subsequently, a fourth interlayer insulating layer IL4 may be formed on the source structure 670 and the protective layer 690. Subsequently, a third interconnection structure IC3 may be formed in the fourth interlayer insulating layer IL4. The third interconnection structure IC3 may be connected to the contact plug 660 or the source structure 670. For example, the third interconnection structure IC3 may be connected to the contact plug 660 through the protective layer 690.

For reference, after removing the second substrate 600B, the protective layer 690 may also be removed, and in this case, the third interconnection structure IC3 may be connected to the contact plug 660 through the fourth interlayer insulating layer IL4.

In addition, in an embodiment a bonding layer may be formed in the process of forming the first wafer WF1 or the second wafer WF2. For example, referring to FIGS. 7 and 8, the bonding layer 580 may be formed over or on the first wafer WF1 or the second wafer WF2. For example, the bonding layer may include nitride. Therefore, the bonding force between the first wafer WF1 and the second wafer WF2 may increase.

According to the manufacturing method described above, the protective layer 690 may be formed in the second substrate 600B. The protective layer 690 may be formed in the sealing region surrounding the chip region. The protective layer 690 may prevent or minimize damage to the second substrate 600B in the process of forming the contact plugs 660 of the contact array CTA.

Although embodiments according to the technical concepts of the present disclosure have been described with reference to the accompanying drawings, the embodiments of the present disclosure are not limited to the above-described embodiments. Within the scope of the technical concepts of the present disclosure described in the claims, various forms of substitution, modification, and change of the embodiments will be possible by those skilled in the art to which the present disclosure belongs.

What is claimed is:

1. A semiconductor device comprising:
a cell array disposed over or on a peripheral circuit;
a bonding pad for electrically connecting the peripheral circuit with the cell array; and
a bonding via extending inside the bonding pad.

2. The semiconductor device of claim 1, further comprising:
an interlayer insulating layer surrounding a first portion; and
a bonding layer surrounding a second portion.

3. The semiconductor device of claim 1, further comprising:
a bonding layer surrounding a first portion; and
an interlayer insulating layer surrounding a first portion.

4. The semiconductor device of claim 3, wherein the interlayer insulating layer includes a material different from the bonding layer.

5. The semiconductor device of claim 4, wherein the interlayer insulating layer includes oxide and the bonding layer includes nitride, and
wherein the bonding pad includes a two-part shape including the first portion and the second portion having different widths.

6. The semiconductor device of claim 1, further comprising:
a contact array disposed over or on the peripheral circuit and positioned at a level corresponding to the cell array.

7. The semiconductor device of claim 6, further comprising:
a protective layer disposed over or on the contact array.

8. The semiconductor device of claim 7, further comprising:
an interconnection structure electrically connected to the contact array through the protective layer.

9. The semiconductor device of claim 7, wherein the protective layer includes oxide.

10. The semiconductor device of claim 1, further comprising:
a source structure disposed over or on the cell array.

11. The semiconductor device of claim 10, further comprising:
an interconnection structure disposed over or on the source structure and electrically connected to the source structure.

12. A semiconductor device comprising:
a peripheral circuit comprising a plurality of transistors;
a cell array and a contact array positioned adjacent to each other over the peripheral circuit;
bonding pads for electrically connecting the peripheral circuit with the cell array and for electrically connecting the peripheral circuit with the contact array,
each of the bonding pads comprising first portion and second portion;
wherein the first portion has a first width and is in electrical connection with at least one transistor of the peripheral circuit,
wherein the second portion has a second width that is less than the first width of the first portion, and
wherein a bonding via electrically connecting the bonding pad with the contact array or the cell array extends partially inside the first portion of the bonding pad.

13. The semiconductor device of claim 12, further comprising:
an interlayer insulating layer surrounding the first portion; and
a bonding layer surrounding the second portion.

14. The semiconductor device of claim 12, further comprising:
a bonding layer surrounding the first portion; and
an interlayer insulating layer surrounding the first portion.

15. The semiconductor device of claim 14, wherein the interlayer insulating layer includes a material different from the bonding layer.

16. The semiconductor device of claim 15, wherein the interlayer insulating layer includes oxide and the bonding layer includes nitride.

17. The semiconductor device of claim 12, further comprising:
a protective layer disposed over or on the contact array.

18. The semiconductor device of claim 17, further comprising:
an interconnection structure electrically connected to the contact array through the protective layer.

19. The semiconductor device of claim 17, wherein the protective layer includes oxide.

20. The semiconductor device of claim 12, further comprising:
a source structure disposed over or on the cell array.

21. The semiconductor device of claim 20, further comprising:
an interconnection structure disposed over or on the source structure and electrically connected to the source structure.

22. A method of manufacturing a semiconductor device, the method comprising:
forming a first wafer including a preliminary bonding pad;
forming a second wafer including a substrate, an interlayer insulating layer disposed over or on the substrate, a bonding via positioned in the interlayer insulating layer, and a trench exposing the bonding via;
bonding the first wafer and the second wafer so that the preliminary bonding pad and the bonding via contact each other; and
forming a bonding pad surrounding the bonding via by expanding the preliminary bonding pad into the trench.

23. The method of claim 22, wherein forming the second wafer comprises:
forming the interlayer insulating layer on the substrate;
forming the bonding via in the interlayer insulating layer; and
forming the trench exposing a sidewall of the bonding via, in the interlayer insulating layer.

24. The method of claim 22, wherein forming the second wafer comprises:
forming the interlayer insulating layer on the substrate;
forming a bonding layer on the interlayer insulating layer;
forming the bonding via in the interlayer insulating layer and the bonding layer; and
forming the trench in the bonding layer.

25. The method of claim 22, wherein forming the second wafer comprises:
forming a protective layer in the substrate; and
forming a contact array including a contact plug disposed over or on the protective layer.

26. The method of claim 25, further comprising:
exposing the protective layer by removing the substrate; and
forming an interconnection structure connected to the contact plug through the protective layer.

27. The method of claim 25, further comprising:
exposing the contact plug by removing the substrate and the protective layer; and
forming an interconnection structure connected to the contact plug.

28. The method of claim 22, wherein forming the second wafer comprises forming a cell array including channel structures disposed over or on the substrate.

29. The method of claim 28, further comprising:
removing the substrate; and
forming a source structure connected to the channel structures.
